(19) United States
(12) Patent Application Publication
(10) Pub. No.: US 2025/0287850 A1
(43) Pub. Date: Sep. 11, 2025

(54) SOT-MRAM Device and Method for Manufacturing Thereof

(71) Applicant: ZHEJIANG HIKSTOR TECHNOLOGY CO., LTD., Hangzhou, Zhejiang (CN)

(72) Inventors: Lijie SHEN, Hangzhou, Zhejiang (CN); Enlong LIU, Hangzhou, Zhejiang (CN); Shikun HE, Hangzhou,Zhejiang (CN)

(21) Appl. No.: 18/858,647

(22) PCT Filed: Mar. 10, 2023
(86) PCT No.: PCT/CN2023/080800

§ 371 Date: Oct. 21, 2024

(30) Foreign Application Priority Data
Jul. 6, 2022 (CN) 202210791519.0

(51) Int. Cl. H10N 50/10; G11C 11/16; H10N 50/01; H10N 50/80

(52) U.S. Cl. CPC H10N 50/10; G11C 11/161; H10N 50/01; H10N 50/80

(57) ABSTRACT

The present disclosure provides an SOT-MRAM device and a method for manufacturing thereof. The SOT-MRAM device includes: two separate bottom electrodes; a finned support structure located between the two bottom electrodes; a conductive layer located on sidewalls of the finned support structure and extending over the two bottom electrodes; and a memory cell stacked structure located above the finned support structure and the conductive layer on the sidewalls of the finned support structure.

### CROSS-REFERENCE TO RELATED APPLICATION

The present disclosure claims priority to patent application Ser. No. 202210791519.0 filed to the China National Intellectual Property Administration on Jul. 6, 2022 and entitled “SOT-MRAM device and method for manufacturing thereof”, which is incorporated herein by reference in its entirety.

### TECHNICAL FIELD

The present disclosure relates to the technical field of magnetic memories, and in particular, to a spin-orbit torque magnetic random-access memory (SOT-MRAM) device and a method for manufacturing thereof.

### BACKGROUND

As the next-generation non-volatile magnetic random access memory, the optimization of a manufacturing process for a spin-orbit torque magnetic random access memory (SOT-MRAM) is crucial, with a device yield being a key metric. In the current manufacturing process, a magnetic tunnel junction is etched on a spin-orbit torque (SOT) effect layer. Given that the thickness of the SOT effect layer in the SOT-MRAM is only a few nanometers, the etching requirements for a magnetic tunnel junction material layer are very high. It is necessary to ensure a sufficient etching amount to reduce short circuits, while also avoiding device failure caused by etching through the SOT effect layer in an over-etching process, and as a result, an etching process window is very small.

### SUMMARY

To solve the above problems, the present disclosure provides an SOT-MRAM device and a method for manufacturing thereof, thereby providing a larger over-etching window.

According to one aspect, the present disclosure provides an SOT-MRAM device, including:
two separate bottom electrodes;
a finned support structure located between the two bottom electrodes;
a conductive layer located on a sidewalls of the finned support structure and extending over the two bottom electrodes; and
a memory cell stacked structure located above the finned support structure and the conductive layer on the sidewalls of the finned support structure, and a height of the finned support structure is greater than an over-etching amount of the memory cell stacked structure, and a sum of widths of the finned support structure and the conductive layer on the sidewalls of the finned support structure is less than a width of the memory cell stacked structure.

In some embodiments, the memory cell stacked structure includes a spin-orbit torque effect layer, a magnetic tunnel junction, and a hard mask layer stacked from bottom to top, and positions below two ends of the spin-orbit torque effect layer are connected to the conductive layer.

In some embodiments, a material of the finned support structure is insulating dielectric.

In some embodiments, a material of the conductive layer is metal.

In some embodiments, the SOT-MRAM device further includes: a protective layer located around the memory cell stacked structure; and
a top electrode located above the memory cell stacked structure.
In some embodiments, the SOT-MRAM device further includes: a top interconnect structure formed above the top electrode, where the top interconnect structure includes a top via, and the top via communicates with the top electrode.

According to another aspect, the present disclosure provides a method for manufacturing an SOT-MRAM device, including:
a bottom electrode metal layer and a first dielectric layer are deposited, a patterned groove of a finned support structure is formed in the bottom electrode metal layer and the first dielectric layer through photolithography and etching, and the first dielectric layer is removed to obtain two separate parts of the bottom electrode metal layer;
a second dielectric layer is deposited, and the second dielectric layer is planarized;
photolithography and etching is performed on the second dielectric layer to form the finned support structure and expose the bottom electrode metal layer;
a conductive layer material and a third dielectric layer are deposited, and the conductive layer material and the third dielectric layer are planarized to expose the finned support structure;
a memory cell stacked structure and a protective layer thereof are formed above the finned support structure; and
a top electrode is formed.

In some embodiments, the top electrode is formed includes:
a fourth dielectric layer is deposited and the fourth dielectric layer is planarized to expose the hard mask layer;
a top electrode metal layer is deposited; and
a top electrode pattern is obtained through photolithography, and stacked layers are etched from the top electrode metal layer to the bottom electrode metal layer.

According to another aspect, the present disclosure provides a method for manufacturing an SOT-MRAM device, including:
a bottom electrode metal layer and a first dielectric layer are deposited, a bottom electrode pattern is formed in the bottom electrode metal layer and the first dielectric layer through photolithography and etching, and the first dielectric layer is removed to obtain two separate bottom electrodes;
a second dielectric layer is deposited and the second dielectric layer is planarized;
photolithography and etching is performed on the second dielectric layer to form a finned support structure and expose the two separate bottom electrodes;
a conductive layer material and a third dielectric layer are deposited and the conductive layer material and the third dielectric layer are planarized to expose the finned support structure;
a memory cell stacked structure and a protective layer thereof are formed above the finned support structure; and
a top electrode is formed.

In some embodiments, the top electrode is formed includes:
a fourth dielectric layer is deposited and the fourth dielectric layer is planarized to expose a hard mask layer;
a top electrode metal layer is deposited; and
a top electrode pattern is obtained through photolithography, and stacked layers are etched from the top electrode metal layer to the conductive layer.

In some embodiments, the memory cell stacked structure and the protective layer thereof are formed above the finned support structure includes:
a spin-orbit torque effect material layer, a magnetic tunnel junction material layer, and a hard mask material layer are sequentially deposited to form a stacked structure;
the stacked structure is etched, and the stacked structure is over-etched to the third dielectric layer; and
the protective layer is deposited.

### BRIEF DESCRIPTION OF THE DRAWINGS

FIG. 1 is a schematic diagram of a structure of an SOT-MRAM device according to an embodiment of the present disclosure;

FIG. 2 is a schematic diagram of a structure of an SOT-MRAM device according to another embodiment of the present disclosure;

FIG. 3A to FIG. 3K illustrate schematic diagrams of a technological process of a method for manufacturing an SOT-MRAM device according to an embodiment of the present disclosure; and

FIG. 4A to FIG. 4K illustrate schematic diagrams of a technological process of a method for manufacturing an SOT-MRAM device according to another embodiment of the present disclosure.

### DETAILED DESCRIPTION OF THE EMBODIMENTS

To make objectives, technical solutions, and advantages of embodiments of the present disclosure clearer, the technical solutions in the embodiments of the present disclosure are clearly and completely described with reference to the accompanying drawings in the embodiments of the present disclosure. However, it should be understood that these descriptions are merely illustrative and are not intended to limit the scope of the present disclosure. Based on the embodiments of the present disclosure, all other embodiments obtained by those of ordinary skill in the art without creative labor shall fall within the scope of protection of the present disclosure. Additionally, in the following description, descriptions of well-known structures and technologies are omitted to avoid unnecessarily obscuring the concepts of the present disclosure.

The accompanying drawings illustrate schematic diagrams of various structures of the embodiments of the present disclosure. These figures are not drawn to scale. For clarity, some details are enlarged, and some details may be omitted. The shapes of various regions and layers shown in the figures, as well as their relative sizes and positional relationships, are merely illustrative. In practice, there may be deviations due to manufacturing tolerances or technical limitations, and those skilled in the art can additionally design regions/layers with different shapes, sizes, and relative positions according to actual needs.

In the context of the present disclosure, when one layer/element is described as being located “on” another layer/element, the layer/element may be directly located on the another layer/element, or there may be an intermediate layers/element between them. Additionally, if one layer/element is located “above” the another layer/element in one direction, when the direction is reversed, the layer/element may be located “below” the another layer/element.

Some implementations of the present disclosure are described in detail with reference to the accompanying drawings below. The following embodiments and features in the embodiments may be combined without conflicts.

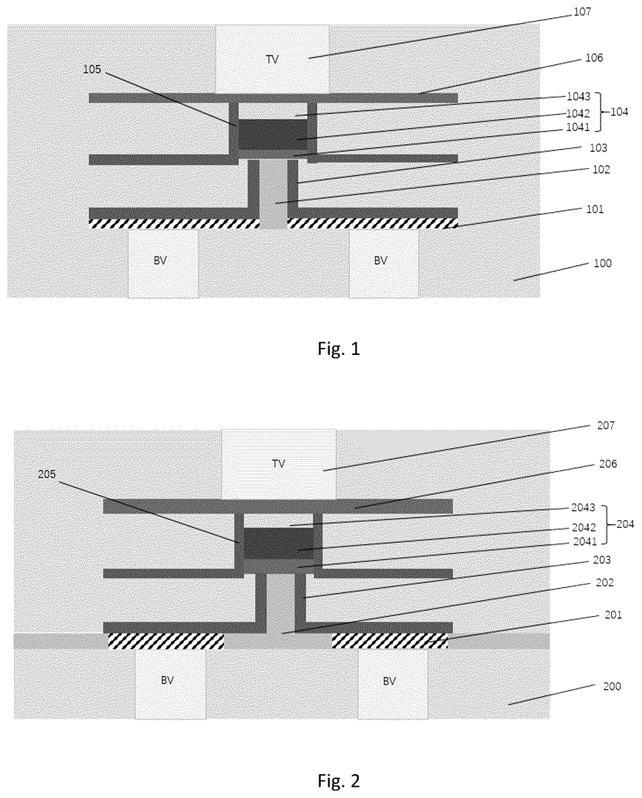

An embodiment of the present disclosure provides an SOT-MRAM device. As shown in FIG. 1, the SOT-MRAM device includes:
two separate bottom electrodes 101;
a finned support structure 102 located between the two bottom electrodes;
a conductive layer 103 located on a sidewalls of the finned support structure 102 and extending over the two bottom electrodes 101; and
a memory cell stacked structure 104 located above the finned support structure 102 and the conductive layer 103 on the sidewalls of the finned support structure 102, where a height of the finned support structure 102 is greater than an over-etching amount of the memory cell stacked structure, and a sum of widths of the finned support structure 102 and the conductive layer 103 on the sidewalls of the finned support structure 102 is less than a width of the memory cell stacked structure.

In this embodiment, as shown in FIG. 1, the memory cell stacked structure 104 includes a spin-orbit torque (SOT) effect layer 1041, a magnetic tunnel junction 1042, and a hard mask (HM) layer 1043 stacked from bottom to top, and positions below two ends of the spin-orbit torque effect layer are connected to the conductive layer 103.

The structure of the above SOT-MRAM device adds the finned support structure 102, and a material of the finned support structure 102 is insulating dielectric, which may be selected from silicon nitride, silicon oxide, or silicon oxynitride. The memory cell stacked structure is formed through an etching process, and reverse sputter may be removed through an over-etching method, thereby enlarging an etching window. The positions below two ends of the spin-orbit torque (SOT) effect layer communicate with the two bottom electrodes through the conductive layer 103, thereby forming a current path. A material of the conductive layer 103 is metal, preferably any one of W, Ta, Ti, TaN, and TiN.

Referring to FIG. 1, the SOT-MRAM device also includes a bottom interconnect structure 100 formed on a substrate. The bottom interconnect structure includes two bottom vias (BVs). The bottom vias are filled with metal, typically copper, and the two bottom vias communicate with the two bottom electrodes 101 respectively.

Additionally, the SOT-MRAM device further includes a protective layer 105 located around the memory cell stacked structure 104, and a top electrode 106 located above the memory cell stacked structure 104. The bottom electrodes 101 and the top electrode 106 are typically any one of Ta, Ti, TaN, and TiN.

A top interconnect structure 107 is arranged above the top electrode 106, and includes a top via (TV). The top via is filled with metal, typically copper, and the top via communicates with the top electrode.

FIG. 2 is a schematic diagram of a structure of an SOT-MRAM device according to another embodiment of the present disclosure. As shown in FIG. 2, the SOT-MRAM device includes:
two separate bottom electrodes 201;
a finned support structure 202 located between the two bottom electrodes;
a conductive layer 203 located on a sidewalls of the finned support structure 202 and extending over the two bottom electrodes 201; and
a memory cell stacked structure 204 located above the finned support structure 202 and the conductive layer 203 on the sidewalls of the finned support structure 202, where a height of the finned support structure 202 is greater than an over-etching amount of the memory cell stacked structure 204, and a sum of widths of the finned support structure 202 and the conductive layer 203 on the sidewalls of the finned support structure 202 is less than a width of the memory cell stacked structure.

The memory cell stacked structure 204 includes a spin-orbit torque (SOT) effect layer 2041, a magnetic tunnel junction 2042, and a hard mask (HM) layer 2043 stacked from bottom to top, and positions below two ends of the spin-orbit torque effect layer 2041 are connected to the conductive layer 203.

Compared with FIG. 1, the difference in FIG. 2 lies in a slightly different shape of the finned support structure 202, and the finned support structure 202 has extension parts with a certain length towards the bottom electrodes on two sides. This is due to different manufacturing processes, which will be described in detail later. For other structural features, referring to FIG. 2, the SOT-MRAM device also includes a bottom interconnect structure 200 formed on a substrate. The bottom interconnect structure includes two bottom vias (BVs). The bottom vias are filled with metal, typically copper, and the two bottom vias communicate with the two bottom electrodes 201 respectively.

Additionally, the SOT-MRAM device further includes a protective layer 205 located around the memory cell stacked structure 204, and a top electrode 206 located above the memory cell stacked structure 204. A top interconnect structure 207 is arranged above the top electrode 206, and includes a top via (TV). The top via is filled with metal, typically copper, and the top via communicates with the top electrode. For materials of various layers, reference may be made to the description of the foregoing embodiment.

According to the SOT-MRAM device provided by this embodiment of the present disclosure, the finned support structure with a certain height is manufactured before growing the memory cell film structure. The two sides of the finned support structure are metal conductive layer, which are respectively connected to the pre-prepared vias. According to the present disclosure, a larger over-etching window may be provided to the memory cell film structure, thereby eliminating short circuits caused by reverse sputtering, and then improving a device yield.

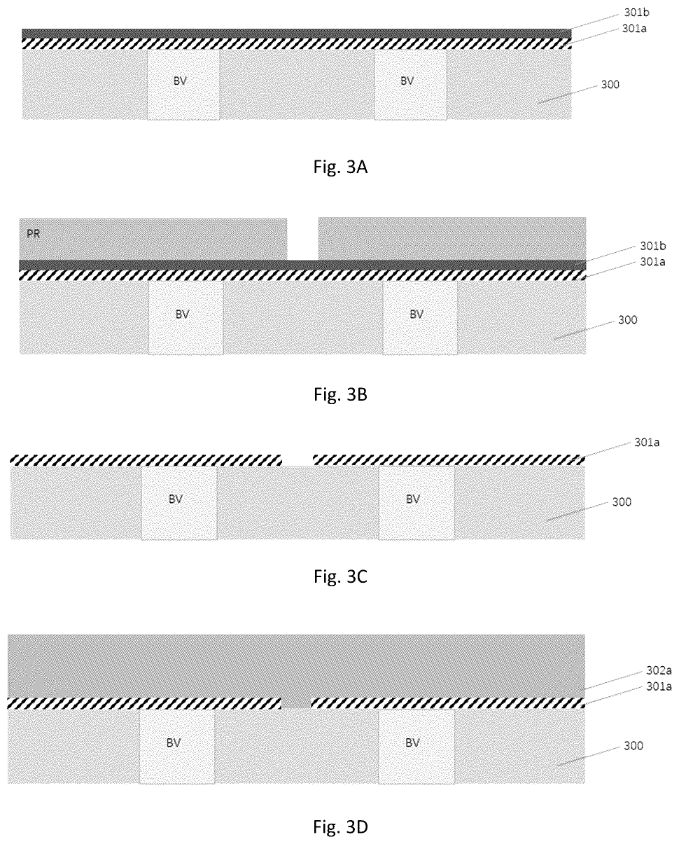

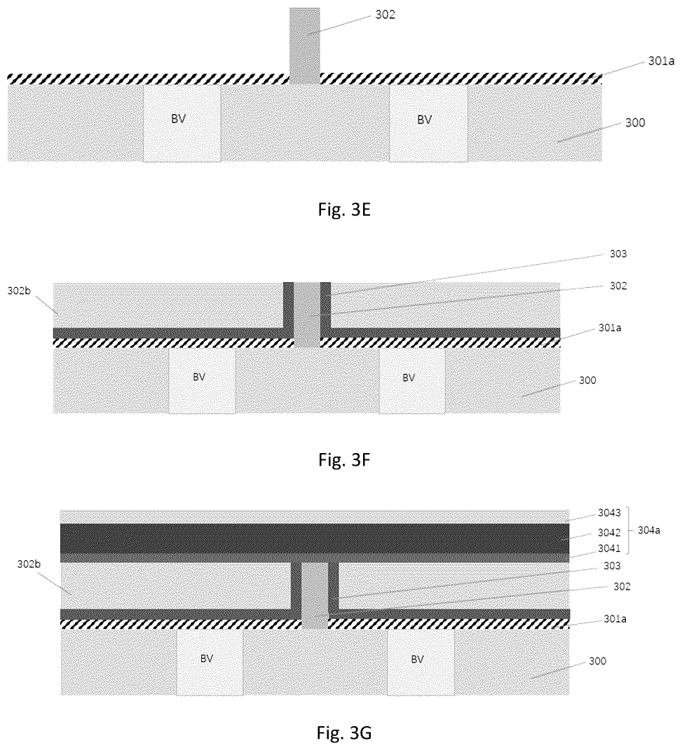

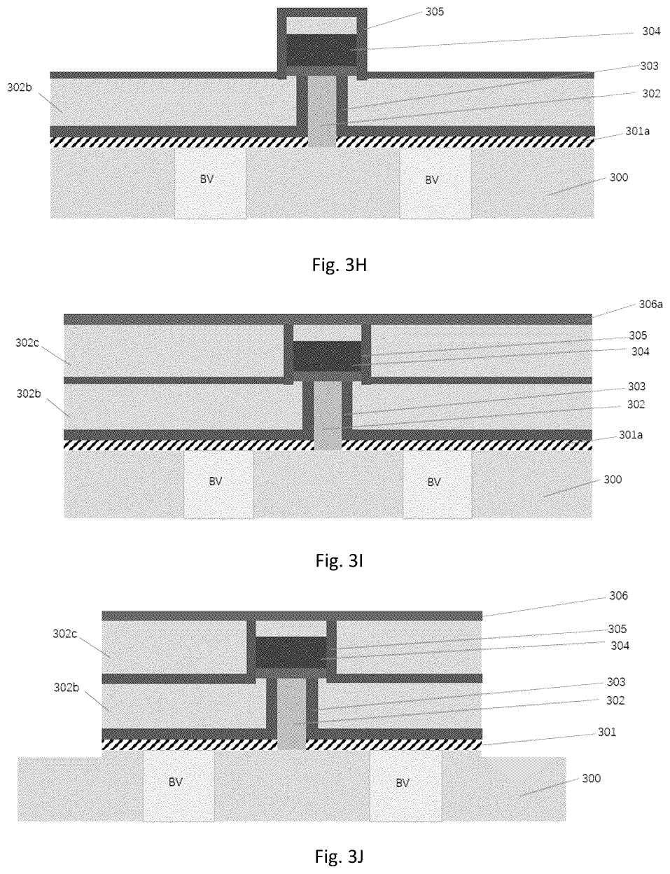

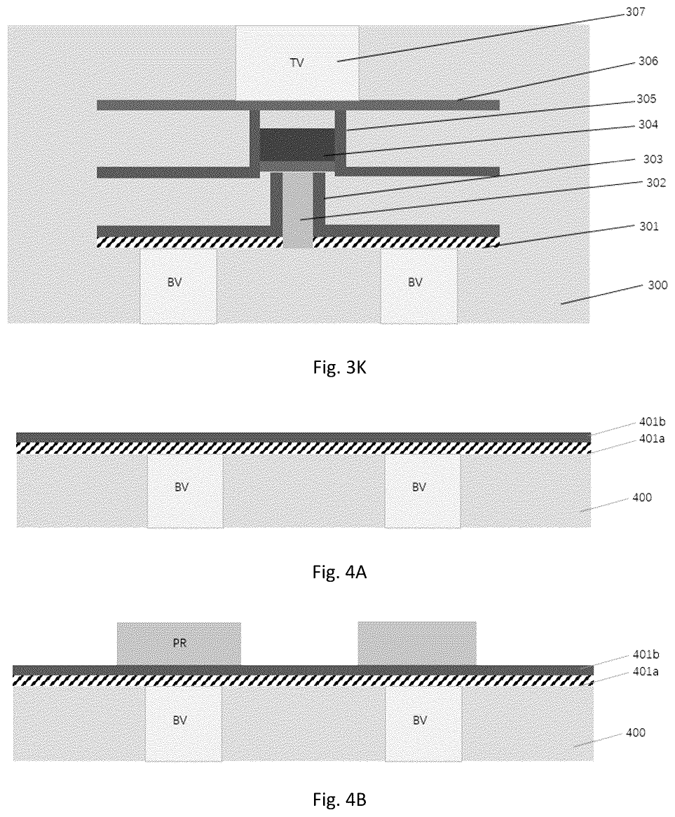

According to another aspect, referring to FIG. 3A to FIG. 3K, another embodiment of the present disclosure provides a method for manufacturing an SOT-MRAM device, specifically including:
referring to FIG. 3A to FIG. 3C, a patterned groove of the finned support structure is formed above a bottom interconnect structure 300. In this embodiment, the bottom interconnect structure 300 has been previously obtained on a substrate, and includes two bottom vias (BVs, also known as bottom metal connection holes), and the bottom vias are filled with metal, typically copper. A bottom electrode metal layer 301a and a first dielectric layer 301b are deposited on the bottom interconnect structure 300, and then photoresist (PR) spin-coating is performed. Through photolithography and etching, the patterned groove of the finned support structure is formed in the bottom electrode metal layer and the first dielectric layer. The first dielectric layer 301b is removed to obtain two separate parts of the bottom electrode metal layer 301a. In this case, bottom electrodes are not fully formed, which can be obtained through one-time etching during subsequent formation of a top electrode.

Referring to FIG. 3D to FIG. 3E, a second dielectric layer 302a is deposited and the second dielectric layer 302a is planarized; and then photolithography and etching are performed on the second dielectric layer to form the finned support structure 302 and expose the bottom electrode metal layer 301a. A position of the finned support structure 302 is kept consistent with the previous patterned groove, and a photolithography process may be implemented using the same photomask. A height of the finned support structure 302 is greater than an over-etching amount of a subsequent memory cell stacked structure.

Referring to FIG. 3F, a conductive layer material and an interlayer dielectric material are deposited, and the conductive layer material and the interlayer dielectric material are planarized to obtain a conductive layer 303 and a third dielectric layer 302b peripheral to the conductive layer 303, and to expose the finned support structure 302.

Referring to FIG. 3G to FIG. 3H, a memory cell stacked structure 304 and a protective layer 305 thereof are formed above the finned support structure 302.

Specifically, within the same equipment, a spin-orbit torque effect material layer 3041 and a magnetic tunnel junction material layer 3042 are continuously deposited, and then a hard mask material layer 3043 is deposited to form a stacked structure 304a. Photolithography and etching are performed on the stacked structure 304a to obtain the memory cell stacked structure 304. When the etching process is performed, over-etching may be performed to the third dielectric layer 302b. Since the height of the finned support structure 302 is greater than an over-etching amount of the memory cell stacked structure 304, a larger over-etching window is provided, thereby eliminating short circuits caused by reverse sputtering and then improving the device yield.

The sum of widths of the finned support structure 302 and the conductive layer 303 on sidewalls of the finned support structure 302 is less than a width of the memory cell stacked structure 304. The protective layer 305 is deposited immediately after etching.

Referring to FIG. 3I to FIG. 3J, a top electrode 306 is formed.

Specifically, an interlayer dielectric material is deposited above and around the memory cell stacked structure 304 and the interlayer dielectric material is planarized to open a top of the memory cell stacked structure, to expose a hard mask layer, and to form a fourth dielectric layer 302c around the protective layer 305;
a top electrode metal layer 306a is deposited; and
a top electrode pattern is obtained through photolithography, and stacked layers from the top electrode metal layer 306a to the bottom electrode metal layer 301a are etched. Bottom electrodes 301 are synchronously obtained while forming the top electrode 306.

Referring to FIG. 3K, after forming the top electrode 306, the method further includes:
a top interconnect structure 307 is formed. Specifically, an interlayer dielectric material is deposited, and after patterning a top via, top metal is deposited to form the top interconnect structure 307.

In the above steps, the interlayer dielectric materials involved in various dielectric layers may be the same material or different materials, which are typically selected from silicon nitride, silicon oxide, or silicon oxynitride.

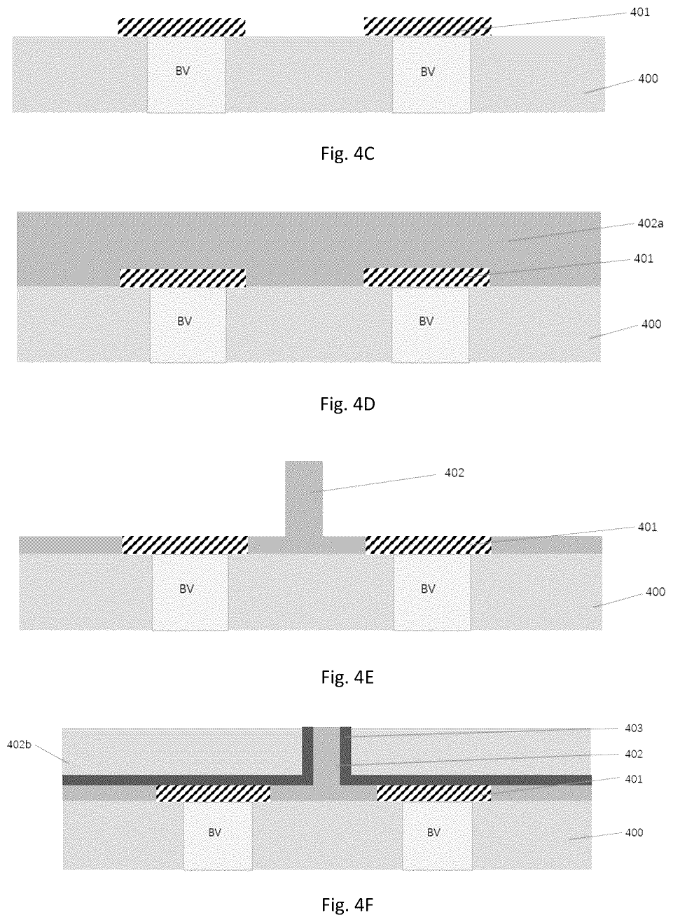

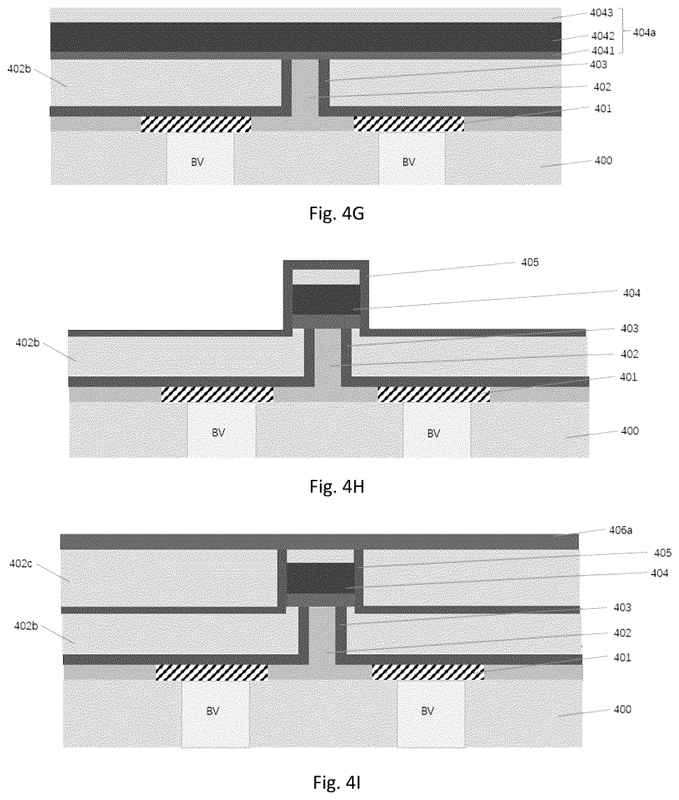

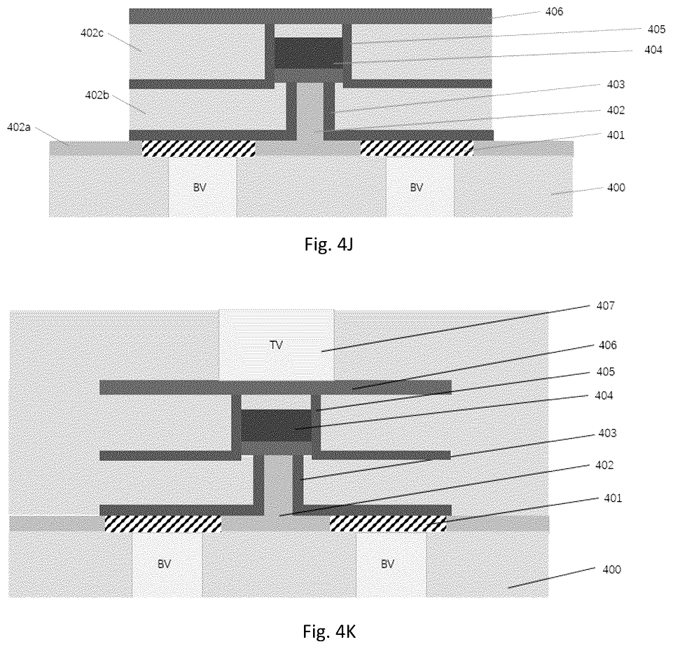

According to another aspect, referring to FIG. 4A to FIG. 4K, another embodiment of the present disclosure provides a method for manufacturing an SOT-MRAM device, specifically including:
referring to FIG. 4A to FIG. 4C, two separate bottom electrodes are formed above a bottom interconnect structure 400. In this embodiment, the bottom interconnect structure 400 has been previously obtained on a substrate, and includes two bottom vias (BVs, also known as bottom metal connection holes), and the bottom vias are filled with metal, typically copper. A bottom electrode metal layer 401a and a first dielectric layer 401b are deposited on the bottom interconnect structure 400, and then photoresist (PR) spin-coating is performed. Through photolithography and etching, a bottom electrode pattern is formed in the bottom electrode metal layer and the first dielectric layer. The first dielectric layer 401b is removed to obtain the two separate bottom electrodes 401.

Referring to FIG. 4D to FIG. 4E, a second dielectric layer 402a is deposited and the second dielectric layer 402a is planarized; and then photolithography and etching are performed on the second dielectric layer to form a finned support structure 402 and expose the bottom electrodes 401. The finned support structure 402 has extension parts with a certain length towards the bottom electrodes on two sides. A height of the finned support structure 402 is greater than an over-etching amount of a subsequent memory cell stacked structure.

Referring to FIG. 4F, a conductive layer material and an interlayer dielectric material are deposited and the conductive layer material and the interlayer dielectric material are planarized to obtain a conductive layer 403 and a third dielectric layer 402b peripheral to the conductive layer 403, and to expose the finned support structure 402.

Referring to FIG. 4G to FIG. 4H, a memory cell stacked structure 404 and a protective layer 405 thereof are formed above the finned support structure 402.

Specifically, within the same equipment, a spin-orbit torque effect material layer 4041 and a magnetic tunnel junction material layer 4042 are continuously deposited, and then a hard mask material layer 4043 is deposited to form a stacked structure 404a. Photolithography and etching are performed on the stacked structure 404a to obtain the memory cell stacked structure 404. When the etching process is performed, over-etching may be performed to the third dielectric layer 402b. Since the height of the finned support structure 402 is greater than an over-etching amount of the memory cell stacked structure 404, a larger over-etching window is provided, thereby eliminating short circuits caused by reverse sputtering and then improving the device yield.

The sum of widths of the finned support structure 402 and the conductive layer 403 on sidewalls of the finned support structure 402 is less than a width of the memory cell stacked structure 404. The protective layer 405 is deposited immediately after etching.

Referring to FIG. 4I to FIG. 4J, a top electrode 406 is formed.

Specifically, an interlayer dielectric material is deposited above and around the memory cell stacked structure 404 and the interlayer dielectric material is planarized to open a top of the memory cell stacked structure, to expose a hard mask layer, and to form a fourth dielectric layer 402c around the protective layer 405;
a top electrode metal layer 406a is deposited; and
a top electrode pattern is obtained through photolithography, stacked layers from the top electrode metal layer 406a to the conductive layer 403 are etched to expose the second dielectric layer 402a below the conductive layer 403. In this step, over-etching may be performed to the second dielectric layer 402a.

Referring to FIG. 4K, after forming the top electrode 406, the method further includes:
a top interconnect structure 407 is formed. Specifically, an interlayer dielectric material is deposited, and after patterning a top via, top metal is deposited to form the top interconnect structure 407.

In the above steps, the interlayer dielectric materials involved in various dielectric layers may be the same material or different materials, which are typically selected from silicon nitride, silicon oxide, or silicon oxynitride.

According to the method for manufacturing the SOT-MRAM device provided by the above embodiment, the finned support structure with a certain height is manufactured before growing the memory cell film structure. The two sides of the finned support structure are metal conductive layer, which are respectively connected to the pre-prepared vias. Then, the memory cell stacked structure is formed through the etching process, and the reverse sputter may be removed through the over-etching method. According to the present disclosure, a larger over-etching window may be provided to the memory cell film structure, thereby eliminating short circuits caused by the reverse sputtering, and then improving the device yield.

In the above description, detailed explanations of technical details such as patterning and etching of various layers are not provided. However, those skilled in the art should understand that various technical means may be used to form layers, regions, etc. of the required shape. Additionally, to form the same structure, those skilled in the art may also design methods that are not entirely the same as the method described above. Further, although the various embodiments are described separately above, it does not mean that the measures in the various embodiments cannot be advantageously combined and used together.

The above descriptions are merely specific implementations of the present disclosure, but the scope of protection of the present disclosure is not limited to this; and any variations or substitutions that can be easily conceived by those skilled in the art within the technical scope disclosed by the present disclosure shall fall within the scope of protection of the present disclosure. Therefore, the scope of protection of the present disclosure shall be subject to the appended claims.

What is claimed is:

1. An SOT-MRAM device, comprising:
two separate bottom electrodes;
a finned support structure located between the two bottom electrodes;
a conductive layer located on sidewalls of the finned support structure and extending over the two bottom electrodes; and
a memory cell stacked structure located above the finned support structure and the conductive layer on the sidewalls of the finned support structure, wherein a height of the finned support structure is greater than an over-etching amount of the memory cell stacked structure, and a sum of widths of the finned support structure and the conductive layer on the sidewalls of the finned support structure is less than a width of the memory cell stacked structure.

2. The SOT-MRAM device as claimed in claim 1, wherein the memory cell stacked structure comprises a spin-orbit torque effect layer, a magnetic tunnel junction, and a hard mask layer stacked from bottom to top, and positions below two ends of the spin-orbit torque effect layer are connected to the conductive layer.

3. The SOT-MRAM device as claimed in claim 1, wherein a material of the finned support structure is insulating dielectric.

4. The SOT-MRAM device as claimed in claim 1, wherein a material of the conductive layer is metal.

5. The SOT-MRAM device as claimed in claim 1, wherein the SOT-MRAM device further comprises:
a protective layer located around the memory cell stacked structure; and
a top electrode located above the memory cell stacked structure.

6. The SOT-MRAM device as claimed in claim 5, wherein the SOT-MRAM device further comprises: a top interconnect structure formed above the top electrode, wherein the top interconnect structure comprises a top via, and the top via communicates with the top electrode.

7. A method for manufacturing an SOT-MRAM device, comprising:
depositing a bottom electrode metal layer and a first dielectric layer, forming a patterned groove of a finned support structure in the bottom electrode metal layer and the first dielectric layer through photolithography and etching, and removing the first dielectric layer to obtain two separate parts of the bottom electrode metal layer;
depositing a second dielectric layer and planarizing the second dielectric layer;
performing photolithography and etching on the second dielectric layer to form the finned support structure and expose the bottom electrode metal layer;
depositing a conductive layer material and a third dielectric layer and planarizing the conductive layer material and the third dielectric layer to expose the finned support structure;
forming a memory cell stacked structure and a protective layer thereof above the finned support structure; and
forming a top electrode.

8. The method as claimed in claim 7, wherein forming the top electrode comprises:
depositing a fourth dielectric layer and planarizing the fourth dielectric layer to expose a hard mask layer of the memory cell stacked structure;
depositing a top electrode metal layer; and
obtaining a top electrode pattern through photolithography, and etching stacked layers from the top electrode metal layer to the bottom electrode metal layer.

9. A method for manufacturing an SOT-MRAM device, comprising:
depositing a bottom electrode metal layer and a first dielectric layer, forming a bottom electrode pattern in the bottom electrode metal layer and the first dielectric layer through photolithography and etching, and removing the first dielectric layer to obtain two separate bottom electrodes;
depositing a second dielectric layer and planarizing the second dielectric layer;
performing photolithography and etching on the second dielectric layer to form a finned support structure and expose the two separate bottom electrodes;
depositing a conductive layer material and a third dielectric layer and the conductive layer material and the third dielectric layer to expose the finned support structure;
forming a memory cell stacked structure and a protective layer thereof above the finned support structure; and
forming a top electrode.

10. The method as claimed in claim 9, wherein forming the top electrode comprises:
depositing a fourth dielectric layer and planarizing the fourth dielectric layer to expose a hard mask layer of the memory cell stacked structure;
depositing a top electrode metal layer; and
obtaining a top electrode pattern through photolithography, and etching stacked layers from the top electrode metal layer to the conductive layer.

11. The method as claimed in claim 7, wherein forming the memory cell stacked structure and the protective layer thereof above the finned support structure comprises:
sequentially depositing a spin-orbit torque effect material layer, a magnetic tunnel junction material layer, and a hard mask material layer to form a stacked structure;
etching the stacked structure, and over-etching the stacked structure to the third dielectric layer; and depositing the protective layer.

12. The SOT-MRAM device as claimed in claim 1, wherein a material of the finned support structure is silicon nitride, silicon oxide, or silicon oxynitride.

13. The SOT-MRAM device as claimed in claim 1, wherein a material of the conductive layer is any one of W, Ta, Ti, TaN, and TiN.

14. The SOT-MRAM device as claimed in claim 1, wherein the SOT-MRAM device further comprises: a bottom interconnect structure formed on a substrate, wherein the bottom interconnect structure comprises two bottom vias, the bottom vias are filled with metal, and the two bottom vias are in one-to-one communication with the two bottom electrodes.

15. The SOT-MRAM device as claimed in claim 1, wherein the finned support structure has extension parts towards the bottom electrodes on two sides.

16. The SOT-MRAM device as claimed in claim 5, wherein materials of the bottom electrodes and the top electrode are independently selected from any one of Ta, Ti, TaN, and TiN.

17. The method as claimed in claim 11, wherein etching the stacked structure, and over-etching the stacked structure to the third dielectric layer comprises:
etching the stacked structure, and over-etching the stacked structure to the third dielectric layer, such that a height of the finned support structure is greater than an over-etching amount of the stacked structure.

18. The method as claimed in claim 7, wherein before depositing the bottom electrode metal layer and the first dielectric layer, the method further comprises: forming a bottom interconnect structure on a substrate, the bottom interconnect structure comprises two bottom vias, and the bottom vias are filled with metal; and
depositing the bottom electrode metal layer and the first dielectric layer comprises: depositing the bottom electrode metal layer and the first dielectric layer on the bottom interconnect structure.

19. The method as claimed in claim 7, wherein after forming the top electrode, the method further comprises:
depositing an interlayer dielectric material;
patterning the interlayer dielectric material to form a top via; and
depositing top metal in the top via to form a top interconnect structure.

20. The method as claimed in claim 9, wherein forming the memory cell stacked structure and the protective layer thereof above the finned support structure comprises:
sequentially depositing a spin-orbit torque effect material layer, a magnetic tunnel junction material layer, and a hard mask material layer to form a stacked structure;
etching the stacked structure, and over-etching the stacked structure to the third dielectric layer; and
depositing the protective layer.
